(19) United States
(12) Patent Application Publication
(10) Pub. No.: US 2023/0182178 A1
(43) Pub. Date: Jun. 15, 2023

(54) CLEANING APPARATUS AND CLEANING METHOD

(71) Applicant: Powerchip Semiconductor Manufacturing Corporation, Hsinchu (TW)

(72) Inventors: Chun-Chi Chou, Hsinchu City (TW); Chung-Ming Kuo, Hsinchu County (TW)

(73) Assignee: Powerchip Semiconductor Manufacturing Corporation, Hsinchu (TW)

(21) Appl. No.: 17/669,385

(22) Filed: Feb. 11, 2022

(30) Foreign Application Priority Data
Dec. 10, 2021 (TW) 110146309

(51) Int. Cl. B08B 3/02

(52) U.S. Cl. CPC B08B 3/02; B08B 2203/02

(57) ABSTRACT

A cleaning apparatus includes a stage, first annular closed-loop pipelines and first nozzles. The first annular closed-loop pipelines are located above the stage and have different outer diameters. A top-view pattern of the first annular closed-loop pipeline with a larger outer diameter surrounds a top-view pattern of the first annular closed-loop pipeline with a smaller outer diameter. The first nozzles are disposed on each of the first annular closed-loop pipelines.

### CROSS-REFERENCE TO RELATED APPLICATION

This application claims the priority benefit of Taiwan application serial no. 110146309, filed on Dec. 10, 2021. The entirety of the above-mentioned patent application is hereby incorporated by reference herein and made a part of this specification.

### BACKGROUND

### Technical Field

The disclosure relates to a cleaning apparatus and a cleaning method, and more particularly to a cleaning apparatus and a cleaning method having multiple annular closed-loop pipelines.

### Description of Related Art

In many industries, the cleaning process is a very important step. For example, after the semiconductor manufacturing process, the object to be cleaned (e.g., wafer) is subjected to a cleaning process to remove contaminants (e.g., particles) on the object to be cleaned. However, the current cleaning method often has the problem of insufficient cleaning. Therefore, how to facilitate the cleaning effect of the cleaning process still requires continuous efforts.

### SUMMARY

The disclosure provides a cleaning apparatus and a cleaning method, which effectively facilitates the cleaning effect.

The disclosure provides a cleaning apparatus, which includes a stage, multiple first annular closed-loop pipelines, and multiple first nozzles. Multiple first annular closed-loop pipelines are located above the stage and have different outer diameters. The top-view pattern of the first annular closed-loop pipeline with a larger outer diameter surrounds the top-view pattern of the first annular closed-loop pipeline with a smaller outer diameter. Multiple first nozzles are disposed on each first annular closed-loop pipeline.

According to an embodiment of the disclosure, in the cleaning apparatus, the stage may be, for example, a rotating stage.

According to an embodiment of the disclosure, in the cleaning apparatus, the top-view patterns of the multiple first annular closed-loop pipelines may be concentric ring-like patterns.

According to an embodiment of the disclosure, in the cleaning apparatus, a spray direction of the multiple first nozzles may be a direction radiating outwards toward a plane where the upper surface of the stage is located, and the angle between the spray direction of the first nozzle and the first annular closed-loop pipeline may be greater than 90 degrees and less than 180 degrees.

According to an embodiment of the disclosure, in the cleaning apparatus, the spray direction of the multiple first nozzles may be perpendicular to the plane where the upper surface of the stage is located.

According to an embodiment of the disclosure, in the cleaning apparatus, the distance between the first nozzle located on the first annular closed-circuit pipeline with a smaller outer diameter and the plane on which the upper surface of the stage is located may be greater than or equal to the distance between the first nozzle located on the first annular closed-loop pipeline with a larger outer diameter and the plane where the upper surface of the stage is located.

According to an embodiment of the disclosure, the cleaning apparatus may further include fluid supply pipeline, valves, and a computer apparatus. The fluid supply pipeline is in communication with the first annular closed-loop pipeline. The valve is located on the fluid supply pipeline. The valve is coupled to the computer apparatus.

According to an embodiment of the disclosure, the cleaning apparatus may further include a component analyzer. The component analyzer is coupled to the computer apparatus.

According to an embodiment of the disclosure, the cleaning apparatus may further include a second annular closed-loop pipeline and multiple second nozzles. The second annular closed-loop pipeline is located below the stage. Multiple second nozzles are disposed on the second annular closed-loop pipeline.

According to an embodiment of the disclosure, in the cleaning apparatus, the spray direction of the multiple second nozzles may be a direction radiating outwards toward a plane where the lower surface of the stage is located, and the angle between the spray direction of the second nozzle and the second annular closed-loop pipeline may be greater than 90 degrees and less than 180 degrees.

According to an embodiment of the disclosure, in the cleaning apparatus, the spray direction of the multiple second nozzles may be perpendicular to the plane where the lower surface of the stage is located.

According to an embodiment of the disclosure, the cleaning apparatus may further include a central pipeline. The top-view pattern of the first annular closed-loop pipeline with the smallest outer diameter may surround the top-view pattern of the opening of the central pipeline.

The disclosure provides a cleaning method including the following steps. A cleaning apparatus is provided. The cleaning apparatus includes a stage, multiple first annular closed-loop pipelines, and multiple first nozzles. The multiple first annular closed-loop pipelines are located above the stage and have different outer diameters. The top-view pattern of the first annular closed-loop pipeline with a larger outer diameter surrounds the top-view pattern of the first annular closed-loop pipeline with a smaller outer diameter. The multiple first nozzles are disposed on each first annular closed-loop pipeline. The object to be cleaned is placed on the stage. The cleaning process is performed on the object to be cleaned by using the cleaning fluid provided by the multiple first nozzles.

According to an embodiment of the disclosure, in the cleaning method, the stage may be rotated while the cleaning process is performed on the object to be cleaned by using the cleaning fluid.

According to an embodiment of the disclosure, in the cleaning method, the multiple first annular closed-loop pipelines may be supplied with cleaning fluid in sequence from the inside to the outside or at the same time.

According to an embodiment of the disclosure, in the cleaning method, the supply time of the cleaning fluid of two adjacent first annular closed-circuit pipelines may overlap.

According to an embodiment of the disclosure, in the cleaning method, the supply time of the cleaning fluid of the two adjacent first annular closed-circuit pipelines may not overlap.

According to an embodiment of the disclosure, the cleaning method may further include the following steps. The cleaning fluid after cleaning the object to be cleaned is obtained. A component analysis is performed on the obtained cleaning fluid to obtain component analysis results. Whether to end the cleaning process is determined based on the component analysis results.

According to an embodiment of the disclosure, the cleaning method may further include the following steps. The feedback control on the process parameters is performed based on the component analysis results.

According to an embodiment of the disclosure, the cleaning method may further include the following steps. Before the cleaning process is performed on the object to be cleaned, the process parameters are automatically adjusted according to the type of the previous process.

Based on the above, in the cleaning apparatus and the cleaning method proposed by the disclosure, the top-view pattern of the first annular closed-loop pipeline with a larger outer diameter surrounds the top-view pattern of the first annular closed-loop pipeline with a smaller outer diameter. Therefore, during the cleaning process, the cleaning fluid provided to the object to be cleaned by the first nozzle on the first annular closed-loop pipeline located on the inner side can push the cleaning fluid provided to the object to be cleaned by the first nozzle on the first annular closed-loop pipeline located on the outer side, thereby effectively facilitating the cleaning effect. In addition, since the multiple first nozzles located on the first annular closed-loop pipeline are distributed in a ring shape, the cleaning range of the nozzles can be wider, and the cleaning effect can be effectively facilitated.

In order to make the aforementioned features and advantages of the disclosure comprehensible, embodiments accompanied with drawings are described in detail below.

### BRIEF DESCRIPTION OF THE DRAWINGS

FIG. 1 is a schematic diagram of a cleaning apparatus according to some embodiments of the disclosure.

FIG. 2 is a schematic top view of annular closed-loop pipelines, nozzles, and an opening of a central pipeline in FIG. 1.

FIG. 3 is a side view of annular closed-loop pipelines, nozzles, a central pipeline, a wafer, and a stage according to some embodiments of the disclosure.

FIG. 4 is a side view of annular closed-loop pipelines, nozzles, a central pipeline, a wafer, and a stage according to other embodiments of the disclosure.

FIG. 5 is a flowchart of a cleaning method according to some embodiments of the disclosure.

### DETAILED DESCRIPTION OF DISCLOSED EMBODIMENTS

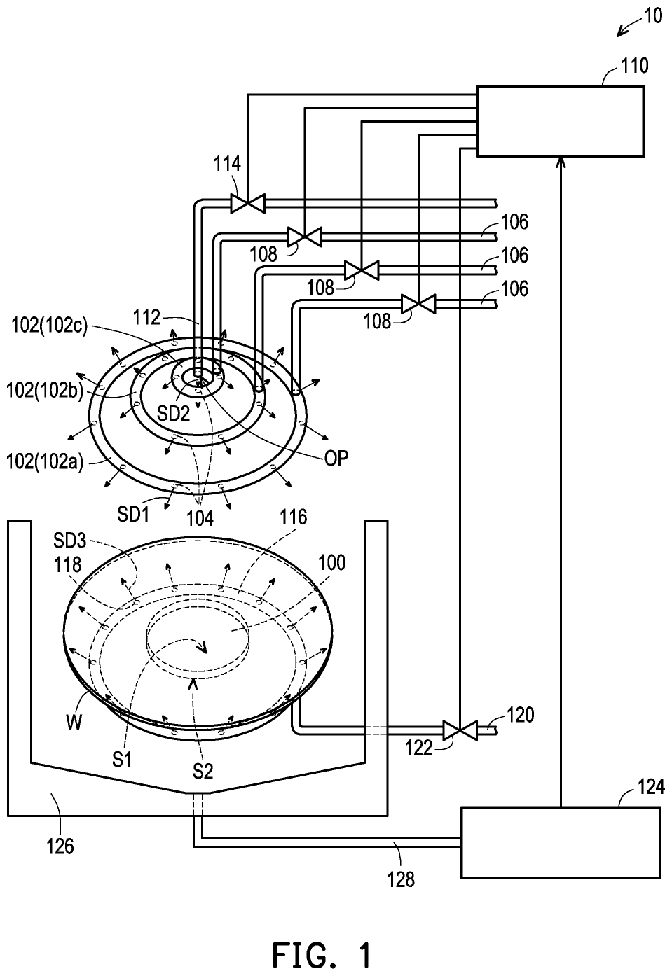

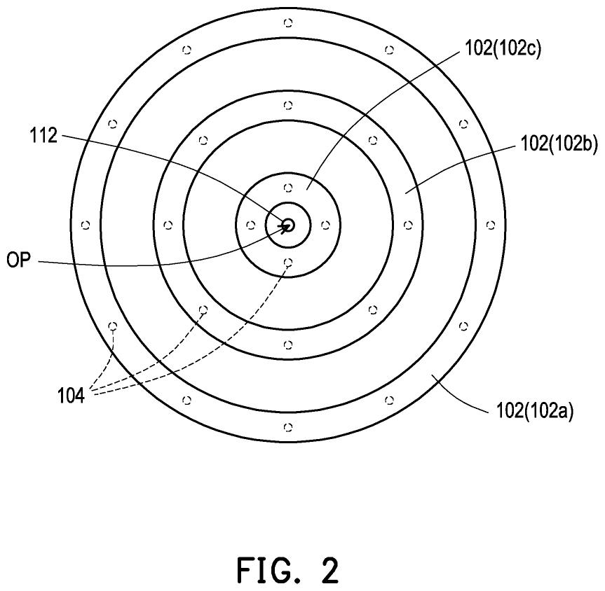

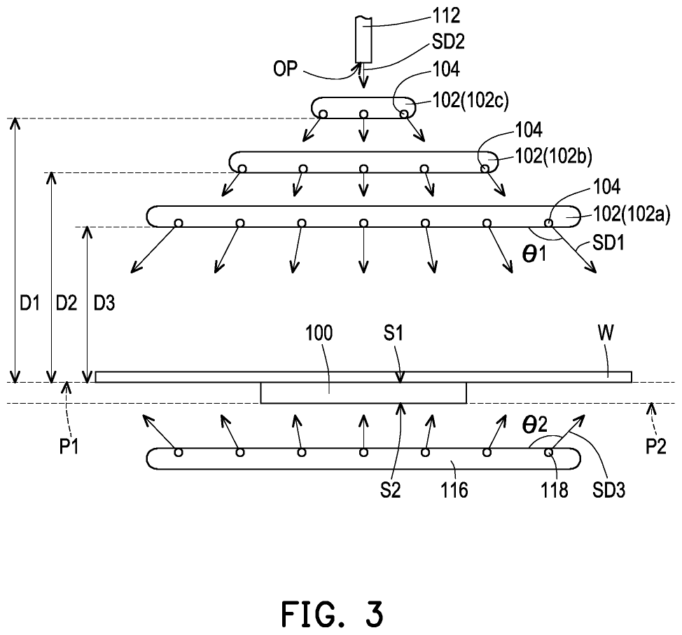

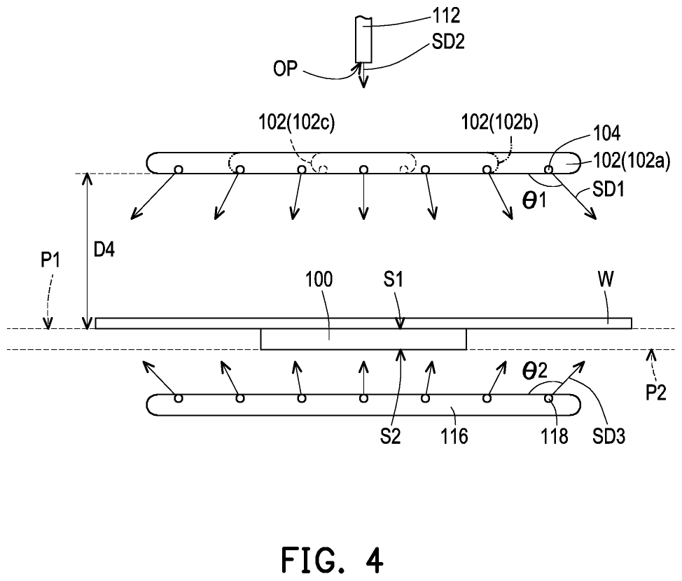

FIG. 1 is a schematic diagram of a cleaning apparatus according to some embodiments of the disclosure. In FIG. 1, the shapes of annular closed-loop pipelines, a wafer, and a stage are shapes viewed from the top at an angle of 45 degrees. FIG. 2 is a schematic top view of the annular closed-loop pipelines, nozzles, and an opening of a central pipeline in FIG. 1. FIG. 3 is a side view of annular closed-loop pipelines, nozzles, a central pipeline, a wafer, and a stage according to some embodiments of the disclosure. FIG. 4 is a side view of annular closed-loop pipelines, nozzles, a central pipeline, a wafer, and a stage according to other embodiments of the disclosure.

Referring to FIGS. 1 to 4, a cleaning apparatus 10 includes a stage 100, multiple annular closed-loop pipelines 102 and multiple nozzles 104. The stage 100 may carry an object W to be cleaned. The stage 100 is, for example, a rotating stage. When the stage 100 is a rotating stage, the stage 100 may be driven to rotate by a driving unit (e.g., a motor) (not shown). The object W to be cleaned may be a wafer or a panel, etc. In this embodiment, the object W to be cleaned is a wafer, but the embodiment merely serves as an example, and the disclosure is not limited thereto.

The multiple annular closed-loop pipelines 102 are located above the stage 100 and have different outer diameters. Since the annular closed-loop pipelines 102 are close-looped, the pressure of the cleaning fluid passing through the annular closed-loop pipelines 102 does not attenuate at terminals. The top-view pattern of the annular closed-loop pipeline 102 with a larger outer diameter surrounds the top-view pattern of the annular closed-loop pipeline 102 with a smaller outer diameter. That is, the top-view pattern of the annular closed-loop pipeline 102 with a smaller outer diameter is located within the top-view pattern of the annular closed-loop pipeline 102 with a larger outer diameter. In this embodiment, the “outer diameter” refers to the “maximum outer diameter” of the object. For example, the top-view pattern of an annular closed-loop pipeline 102a may surround the top-view pattern of an annular closed-loop pipeline 102b, and the top-view pattern of the annular closed-loop pipeline 102b may surround the top-view pattern of an annular closed-loop pipeline 102c (FIG. 2). In some embodiments, the top-view patterns of the multiple annular closed-loop pipelines 102 may be concentric ring-like patterns. In addition, the top-view patterns of the annular closed-loop pipelines 102 include circular ring-like patterns or polygonal ring-like patterns, but the disclosure is not limited thereto. In this embodiment, the top-view patterns of the annular closed-loop pipelines 102 are circular ring-like patterns (FIG. 1 and FIG. 2) as an example. In addition, the number of the annular closed-loop pipelines 102 is not limited to the number shown in the figure. The number of the annular closed-loop pipelines 102 still falls within the scope of the disclosure as long as the number is plural.

The multiple nozzles 104 are provided on each annular closed-loop pipeline 102. The nozzles 104 may clean the front surface and the edge of the object W to be cleaned. During the cleaning process, the nozzle 104 may provide the cleaning fluid to the object W to be cleaned, and the cleaning fluid provided by the nozzle 104 on the annular closed-loop pipeline 102 located on the inner side can push the cleaning fluid provided by the nozzle 104 on the annular closed-loop pipeline 102 located on the outer side, thereby effectively facilitating the cleaning effect to the object W to be cleaned. In addition, since the multiple nozzles 104 located on the annular closed-loop pipeline 102 are distributed in a ring shape, the cleaning range of the nozzles 104 can be wider. Therefore, the cleaning effect is effectively facilitated. In some embodiments, during the cleaning process, the stage 100 may be rotated at the same time. In this way, the object W to be cleaned on the stage 100 is also rotated at the same time, and the cleaning effect of the cleaning fluid is facilitated through the centrifugal force generated by the rotation. In addition, the number of the nozzles 104 is not limited to the number shown in the figure. The number of the nozzles 104 still falls within the scope of the disclosure as long as the number is plural.

In this embodiment, a spray direction SD1 of the multiple nozzles 104 may be a direction radiating outwards toward a plane P1 where an upper surface S1 of the stage 100 is located, and an angle θ1 (FIGS. 3 and 4) between the spray direction SD1 of the nozzle 104 and the annular closed-loop pipeline 102 may be greater than 90 degrees and less than 180 degrees. Thereby, the water column sprayed from the nozzle 104 may have a component of force toward the outer edge of the object W to be cleaned, which helps to further facilitate the cleaning effect. Although the spray direction SD1 of the multiple nozzles 104 in this embodiment is a direction radiating outwards toward the plane P1 where the upper surface S1 of the stage 100 is located, the disclosure is not limited thereto. In other embodiments, the spray direction SD1 of the multiple nozzles 104 may be perpendicular to the plane P1 where the upper surface S1 of the stage 100 is located, that is, the angle θ1 between the spray direction SD1 of the nozzle 104 and the annular closed-loop pipeline 102 may be 90 degrees.

In some embodiments, the distance between the nozzle 104 located on the annular closed-circuit pipeline 102 with a smaller outer diameter and the plane P1 where the upper surface S1 of the stage 100 is located may be greater than the distance between the nozzle 104 located on the annular closed-loop pipeline 102 with a larger outer diameter and the plane P1 where the upper surface of the stage 100 is located, so as to facilitate the cleaning ability to the outer edge of the object W to be cleaned, but the disclosure is no limited thereto. For example, as shown in FIG. 3, a distance D1 between the nozzle 104 on the annular closed-loop pipeline 102c and the plane P1 may be greater than a distance D2 between the nozzle 104 on the annular closed-loop pipeline 102b and the plane P1. In addition, the distance D2 between the nozzle 104 on the annular closed-loop pipeline 102b and the plane P1 may be greater than a distance D3 between the nozzle 104 on the annular closed-loop pipeline 102a and the plane P1.

In other embodiments, the distance between the nozzle 104 located on the annular closed-circuit pipeline 102 with a smaller outer diameter and the plane P1 where the upper surface S1 of the stage 100 is located may be equal to the distance between the nozzle 104 located on the annular closed-loop pipeline 102 with a larger outer diameter and the plane P1 where the upper surface of the stage 100 is located. For example, as shown in FIG. 4, the distance between the nozzle 104 on the annular closed-loop pipeline 102a and the plane P1, the distance between the nozzle 104 on the annular closed-loop pipeline 102b and the plane P1, and the distance between the nozzle 104 on the annular closed-loop pipeline 102c and the plane P1 may be identically set as D4.

Referring to FIG. 1, the cleaning apparatus 10 may further include fluid supply pipelines 106, valves 108 and a computer apparatus 110. The fluid supply pipeline 106 is in communication with the annular closed-loop pipeline 102. The fluid supply pipeline 106 may provide the cleaning fluid to the annular closed-loop line 102. The valve 108 is located on the fluid supply pipeline 106. The valve 108 may control whether the cleaning fluid is supplied to the annular closed-loop pipeline 102. The valve 108 is coupled to the computer apparatus 110. The computer apparatus 110 may control the opening and closing of the valve 108. In this way, the supply mode of the cleaning fluid in the annular closed-loop pipelines 102 is controlled by the computer apparatus 110 and the valves 108.

In some embodiments, as shown in FIGS. 1 to 4, the cleaning apparatus 10 may further include a central pipeline 112. The top-view pattern of the annular closed-loop pipeline 102c having the smallest outer diameter may surround the top-view pattern of an opening OP of the central pipeline 112 (FIG. 2). That is, the top-view pattern of the opening OP of the central pipeline 112 may be located within the top-view pattern of the annular closed-loop pipeline 102c having the smallest outer diameter. The central pipeline 112 may enhance the cleaning effect to the central area of the object W to be cleaned. In some embodiments, a direction SD2 in which the central pipeline 112 supplies the cleaning fluid may be perpendicular to the plane P1 where the upper surface S1 of the stage 100 is located. In some embodiments, a nozzle (not shown) may be provided at top of the opening OP. In other embodiments, the cleaning apparatus 10 may omit the central pipeline 112.

In addition, the cleaning apparatus 10 may further include a valve 114. The valve 114 is located on the central pipeline 112. The valve 114 may control whether to supply the cleaning fluid to the opening OP. The valve 114 is coupled to the computer apparatus 110. The computer apparatus 110 may control the opening and closing of the valve 114. In this way, the supply mode of the cleaning fluid in the central pipeline 112 may be controlled by the computer apparatus 110 and the valve 114.

In addition, as shown in FIGS. 1, 3 and 4, the cleaning apparatus 10 may further include an annular closed-loop pipeline 116 and multiple nozzles 118. The annular closed-loop pipeline 116 is located below the stage 100. Since the annular closed-loop pipeline 116 is close-looped, the pressure of the cleaning fluid passing through the annular closed-loop pipeline 116 does not attenuate at the terminal. The top-view pattern of the annular closed-loop pipeline 116 includes a circular ring-like pattern or a polygonal ring-like pattern, but the disclosure is not limited thereto. In this embodiment, the top-view pattern of the annular closed-loop pipeline 116 is a circular ring (FIG. 1) as an example. The object W to be cleaned and the circular closed-loop pipeline 116 may be located on different sides of the stage 100. The outer diameter of the stage 100 may be smaller than the outer diameter of the object W to be cleaned. The outer diameter of the annular closed-loop pipeline 116 may be smaller than the outer diameter of the object W to be cleaned. In some embodiments, the outer diameter of the annular closed-loop pipeline 116 may be greater than the outer diameter of the stage 100.

Multiple nozzles 118 are provided on the annular closed-loop pipeline 116. The nozzle 118 may clean the back surface and the edge of the object W to be cleaned. In addition, since the multiple nozzles 118 on the annular closed-loop pipeline 116 are distributed in a ring shape, the cleaning range of the nozzles 118 is wider. Therefore, the cleaning effect is effectively facilitated. In addition, the number of the nozzles 118 is not limited to the number shown in the figure. The number of the nozzles 118 falls within the scope of the disclosure as long as the number is plural.

In this embodiment, a spray direction SD3 of the multiple nozzles 118 may be a direction radiating outwards toward a plane P2 where a lower surface S2 of the stage 100 is located, and an angle θ2 (FIGS. 3 and 4) between the spray direction SD3 of the nozzle 118 and the annular closed-loop pipeline 116 may be greater than 90 degrees and less than 180 degrees. Thereby, the water column sprayed from the nozzle 118 may have a component of force toward the outer edge of the object W to be cleaned, which helps to further facilitate the cleaning effect. Although the spray direction SD3 of the multiple nozzles 118 in this embodiment is a direction radiating outwards toward the plane P2 where the lower surface S2 of the stage 100 is located, the disclosure is not limited thereto. In other embodiments, the spray direction SD3 of the multiple nozzles 118 may be perpendicular to the plane P2 where the lower surface S2 of the stage 100 is located, that is, the angle θ2 between the spray direction SD3 of the nozzle 118 and the annular closed-loop pipeline 116 may be 90 degrees.

Referring to FIG. 1, the cleaning apparatus 10 may further include a fluid supply pipeline 120 and a valve 122. The fluid supply pipeline 120 is in communication with the annular closed-loop pipeline 116. The fluid supply pipeline 120 may provide cleaning fluid to the annular closed-loop line 116. The valve 122 is located on the fluid supply pipeline 120. The valve 122 may control whether the cleaning fluid is supplied to the annular closed-loop pipeline 116. The valve 122 is coupled to the computer apparatus 110. The computer apparatus 110 may control the opening and closing of the valve 122. In this way, the supply mode of the cleaning fluid in the annular closed-loop pipeline 116 may be controlled by the computer apparatus 110 and the valve 122.

In some embodiments, as shown in FIG. 1, the cleaning apparatus 10 may further include a component analyzer 124. The component analyzer 124 is coupled to the computer apparatus 110. The component analyzer 124 may analyze the components of the cleaning fluid after cleaning the object W to be cleaned, and transmit the obtained component analysis results to the computer apparatus 110. In this way, the computer apparatus 110 may perform feedback control on the process parameters based on the component analysis results. The process parameters may include the rotation speed of the stage 100, the height of the stage 100, the strength of the water column, and/or the supply sequence of the cleaning fluid, but the disclosure is not limited thereto.

In some embodiments, the cleaning apparatus 10 may further include a collecting container 126 and a conveying pipe 128, but the disclosure is not limited thereto. The collecting container 126 is provided around the stage 100. The collecting container 126 may collect the cleaning fluid after cleaning the object W to be cleaned. The conveying pipe 128 is connected to the collecting container 126 and the component analyzer 124 and is located between the collecting container 126 and the component analyzer 124. The conveying pipe 128 may deliver the cleaning fluid collected in the collecting container 126 to the component analyzer 124 for analysis.

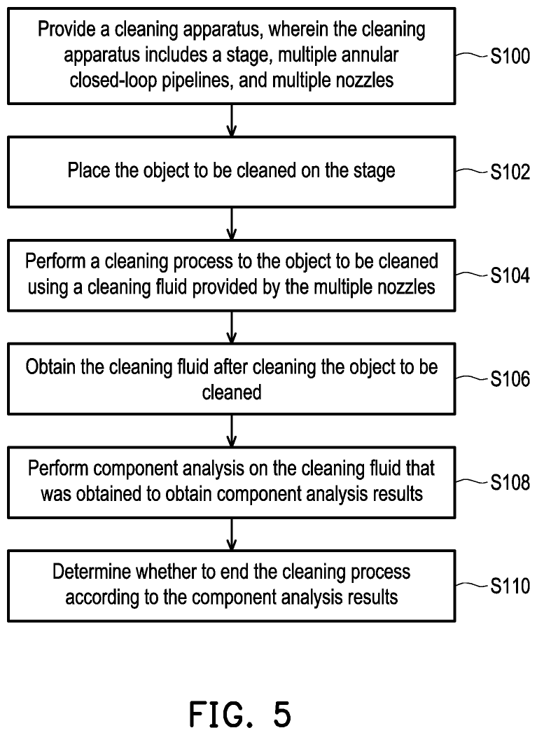

FIG. 5 is a flowchart of a cleaning method according to some embodiments of the disclosure.

Hereinafter, the cleaning method of this embodiment will be described with reference to FIG. 5. Referring to FIGS. 1 to 5, step S100 is performed to provide a cleaning apparatus 10. The cleaning apparatus 10 includes the stage 100, the multiple annular closed-loop pipelines 102 and the multiple nozzles 104. The related content of each component in the cleaning apparatus 10 has been described in detail in the above embodiments, and will not be described again here.

Then, step S102 is performed to place the object W to be cleaned on the stage 100. The object W to be cleaned may be a wafer or a panel, etc. In this embodiment, the object W to be cleaned is a wafer, for example, but the disclosure is not limited thereto.

Then, step S104 is performed to perform a cleaning process on the object W to be cleaned by using the cleaning fluid provided by the multiple nozzles 104. Thereby, the front surface and the edge of the object W to be cleaned is cleaned. In addition, the stage 100 may be rotated while performing the cleaning process on the object W to be cleaned by using the cleaning fluid.

In some embodiments, before performing the cleaning process on the object W to be cleaned, the computer system 110 may automatically adjust process parameters according to the type of the previous process. The process parameters may include the rotation speed of the stage 100, the height of the stage 100, the strength of the water column, and/or the supply sequence of the cleaning fluid, but the disclosure is not limited thereto.

In some embodiments, the multiple annular closed-loop pipelines 102 may be supplied with the cleaning fluid in sequence from the inside to the outside or at the same time. In addition, in the case where the cleaning apparatus 10 includes the central pipeline 112, the central pipeline 112 and the multiple annular closed-loop pipelines 102 may be supplied with cleaning fluid in sequence from the inside to the outside or at the same time. In some embodiments, the supply time of the cleaning fluid of two adjacent annular closed-loop pipelines 102 may or may not overlap. In addition, in the case where the cleaning apparatus 10 includes the central pipeline 112, the supply time of the cleaning fluid for the central pipeline 112 and the adjacent closed-loop pipeline 102 may or may not overlap. For example, the supply mode of the cleaning fluid in the annular closed-loop pipelines 102 and the central pipeline 112 may be controlled by using the computer apparatus 110, the valves 108, and the valve 114.

In some embodiments, in the case where the cleaning apparatus 10 includes the annular closed-loop pipeline 116 and the multiple nozzles 118, the cleaning fluid provided by the multiple nozzles 118 may be used for the cleaning process on the object W to be cleaned. Thereby, the back surface and the edge of the object W to be cleaned is cleaned. In some embodiments, the supply mode of the cleaning fluid in the annular closed-loop pipeline 116 may be intermittent or continuous. For example, the computer apparatus 110 and the valve 122 may control the supply mode of the cleaning fluid in the annular closed-loop pipeline 116.

In this embodiment, the cleaning fluid used may be liquid (e.g., water) or gas (e.g., pure nitrogen (PN₂)). For example, a liquid (e.g., water) may be used to clean the object W to be cleaned first, and then a gas (e.g., pure nitrogen) may be used to dry the object W to be cleaned.

Hereinafter, Table 1 illustrates the supply mode of the cleaning fluid in the annular closed-loop pipelines 102 and the central pipeline 112 in some embodiments of the disclosure. In the embodiment of Table 1 below, the number of the annular closed-loop pipelines 102 is 7 as an example. A valve V0 is located on the central pipeline 112, and valves V1 to V7 are sequentially located on the seven annular closed-loop pipelines 102 disposed from the inside to the outside. For the relevant content of the valve V0, reference is drawn to the description of the valve 114 in the foregoing embodiment, and reference is drawn to the description of the valve 108 in the foregoing embodiment for the relevant content of the valves V1 to V7. In this way, the supply mode of the cleaning fluid in the central pipeline 112 and the annular closed-loop pipelines 102 may be controlled by the computer apparatus 110 and the valves V0 to V7.

It can be seen from Table 1 below that in mode 1 to mode 4, the central pipeline 112 and the multiple annular closed-loop pipelines 102 may be supplied with the cleaning fluid sequentially from the inside to the outside. In mode 1 and mode 4, the supply time of the cleaning fluid of the central pipeline 112 and the adjacent closed-loop line 102 does not overlap, and the supply time of the cleaning fluid of two adjacent closed-loop lines 102 does not overlap. In mode 2 and mode 3, the supply time of the cleaning fluid of the central pipeline 112 and the adjacent closed-loop pipeline 102 overlaps, and the supply time of the cleaning fluid of two adjacent annular closed-loop pipelines 102 overlaps. In addition, the number of cycles of mode 1 to mode 4 may be determined according to process requirements. Besides, the supply mode of the cleaning fluid of the disclosure is not limited to the modes shown in Table 1. Those skilled in the art may optimize the supply mode of the cleaning fluid according to process requirements. In other embodiments, the central pipeline 112 and the multiple annular closed-loop pipelines 102 may simultaneously and continuously supply the cleaning fluid.

TABLE 1

| | mode 1 | | mode 2 | | mode 3 | | mode 4 | |
|---|---|---|---|---|---|---|---|---|
| | Start | | Start | | Start | | Start | |
| valve | time | Duration | time | Duration | time | Duration | time | Duration |
| V0 | 1 sec. | 1 sec. | 1 sec. | 1.5 sec. | 1 sec. | 2 sec. | 1 sec. | 1 sec. |
| V1 | 2 sec. | 1 sec. | 2 sec. | 1.5 sec. | 2 sec. | 2 sec. | 3 sec. | 1 sec. |
| V2 | 3 sec. | 1 sec. | 3 sec. | 1.5 sec. | 3 sec. | 2 sec. | 5 sec. | 1 sec. |
| V3 | 4 sec. | 1 sec. | 4 sec. | 1.5 sec. | 4 sec. | 2 sec. | 7 sec. | 1 sec. |
| V4 | 5 sec. | 1 sec. | 5 sec. | 1.5 sec. | 5 sec. | 2 sec. | 9 sec. | 1 sec. |
| V5 | 6 sec. | 1 sec. | 6 sec. | 1.5 sec. | 6 sec. | 2 sec. | 11 sec. | 1 sec. |
| V6 | 7 sec. | 1 sec. | 7 sec. | 1.5 sec. | 7 sec. | 2 sec. | 13 sec. | 1 sec. |
| V7 | 8 sec. | 1 sec. | 8 sec. | 1.5 sec. | 8 sec. | 2 sec. | 15 sec. | 1 sec. |

Next, step S106 may be performed to obtain the cleaning fluid after cleaning the object W to be cleaned. In some embodiments, the collecting container 126 may be used to obtain the cleaning fluid after cleaning the object W to be cleaned, but the disclosure is not limited thereto.

Furthermore, step S108 may be performed to perform a component analysis on the obtained cleaning fluid to obtain the component analysis results. For example, the component analysis on the obtained cleaning fluid may be performed by using the component analyzer 124. In some embodiments, the obtained cleaning fluid may be delivered to the component analyzer 124 for analysis through the conveying pipe 128, but the disclosure is not limited thereto.

In some embodiments, feedback control on the process parameters may be performed based on the component analysis results. For example, after the component analysis results are obtained by the component analyzer 124, the component analysis results may be sent to the computer apparatus 110 to perform feedback control on the process parameters. The process parameters may include the rotation speed of the stage 100, the height of the stage 100, the strength of the water column, and/or the supply sequence of the cleaning fluid, but the disclosure is not limited thereto.

Subsequently, step S110 may be performed to determine whether to end the cleaning process according to the component analysis results. For example, when water is used as the cleaning fluid, if the component analysis results show that the collected cleaning fluid does not contain a component to be removed or is close to pure water, it is determined that the cleaning has been completed and the cleaning process may be ended. Alternatively, if the component analysis results show that the collected cleaning fluid contains the component to be removed or is not close to pure water, it is determined that the cleaning has not been completed and the cleaning process is continued.

In this embodiment, the automated control of the cleaning process may be realized with steps S106, S108, and S110, but the disclosure is not limited thereto. In other embodiments, step S106, step S108, and step S110 may be omitted.

Based on the above, in the cleaning apparatus 10 and the cleaning method according to the embodiments, the top-view pattern of the annular closed-loop pipeline 102 with a larger outer diameter surrounds the top view pattern of the annular closed-loop pipeline 102 with a smaller outer diameter. Therefore, during the cleaning process, the cleaning fluid provided to the object W to be cleaned by the nozzles 104 on the annular closed-loop pipeline 102 located on the inner side can push the cleaning fluid provided to the object W to be cleaned by the nozzles 104 on the annular closed-loop pipeline 102 located on the outer side, thereby effectively facilitating the cleaning effect. In addition, since the multiple nozzles 104 located on the annular closed-loop pipeline 102 are distributed in a ring shape, the cleaning range of the nozzles 104 can be wider. Therefore, the cleaning effect is effectively facilitated.

To sum up, in the cleaning apparatus and the cleaning method of the embodiments, since the cleaning apparatus includes multiple annular closed-loop pipelines, and the cleaning fluid provided to the object to be cleaned by the nozzles on the annular closed-loop pipelines on the inner side can push the cleaning fluid provided to the object to be cleaned by the nozzle on the annular closed-loop pipeline on the outer side, the cleaning effect can be effectively facilitated. In addition, since the multiple nozzles located on the annular closed-loop pipeline are distributed in a ring shape, the cleaning range of the nozzles can be wider. Therefore, the cleaning effect can be effectively facilitated.

Although the disclosure has been described in detail with reference to the above embodiments, they are not intended to limit the disclosure. Those skilled in the art should understand that it is possible to make changes and modifications without departing from the spirit and scope of the disclosure. Therefore, the protection scope of the disclosure shall be defined by the following claims.

1. A cleaning apparatus, comprising:
a stage;
a plurality of first annular closed-loop pipelines, located above the stage and having different outer diameters, wherein a top-view pattern of the first annular closed-loop pipeline with a larger outer diameter surrounds a top-view pattern of the first annular closed-loop pipeline with a smaller outer diameter; and
a plurality of first nozzles, disposed on each of the first annular closed-loop pipelines.

2. The cleaning apparatus according to claim 1, wherein the stage comprises a rotating stage.

3. The cleaning apparatus according to claim 1, wherein the top-view patterns of the plurality of first annular closed-loop pipelines comprise concentric ring-like patterns.

4. The cleaning apparatus according to claim 1, wherein a spray direction of the plurality of first nozzles is a direction radiating outwards toward a plane where an upper surface of the stage is located, and an angle between the spray direction of the first nozzle and the first annular closed-loop pipeline is greater than 90 degrees and less than 180 degrees.

5. The cleaning apparatus according to claim 1, wherein a spray direction of the plurality of first nozzles is perpendicular to a plane where an upper surface of the stage is located.

6. The cleaning apparatus according to claim 1, wherein a distance between the first nozzle located on the first annular closed-loop pipeline with the smaller outer diameter and a plane where an upper surface of the stage is located is greater than or equal to a distance between the first nozzle located on the first annular closed-loop pipeline with the larger outer diameter and the plane where the upper surface of the stage is located.

7. The cleaning apparatus according to claim 1, further comprising:
a fluid supply pipeline, in communication with the first annular closed-loop pipelines;
a valve, located on the fluid supply pipeline; and
a computer apparatus, wherein the valve is coupled to the computer apparatus.

8. The cleaning apparatus according to claim 7, further comprising:
a component analyzer, coupled to the computer apparatus.

9. The cleaning apparatus according to claim 1, further comprising:
a second annular closed-loop pipeline, located below the stage; and
a plurality of second nozzles, disposed on the second annular closed-loop pipeline.

10. The cleaning apparatus according to claim 9, wherein a spray direction of the plurality of second nozzles is a direction radiating outwards toward a plane where a lower surface of the stage is located, and an angle between the spray direction of the second nozzle and the second annular closed-loop pipeline is greater than 90 degrees and less than 180 degrees.

11. The cleaning apparatus according to claim 9, wherein a spray direction of the plurality of second nozzles is perpendicular to a plane where a lower surface of the stage is located.

12. The cleaning apparatus according to claim 1, further comprising:
a central pipeline, wherein a top-view pattern of the first annular closed-loop pipeline with a smallest outer diameter surrounds a top-view pattern of an opening of the central pipeline.

13. A cleaning method, comprising:
providing a cleaning apparatus, wherein the cleaning apparatus comprises:
a stage,
a plurality of first annular closed-loop pipelines, located above the stage and having different outer diameters, wherein a top-view pattern of the first annular closed-loop pipeline with a larger outer diameter surrounds a top-view pattern of the first annular closed-loop pipeline with a smaller outer diameter, and
a plurality of first nozzles, disposed on each of the first annular closed-loop pipelines;
placing an object to be cleaned on the stage; and
performing a cleaning process on the object to be cleaned by using a cleaning fluid provided by the plurality of first nozzles.

14. The cleaning method according to claim 13, wherein the stage is rotated while the cleaning process is performed on the object to be cleaned by using the cleaning fluid.

15. The cleaning method according to claim 13, wherein the plurality of the first annular closed-loop pipelines are supplied with the cleaning fluid in sequence from inside to outside or at a same time.

16. The cleaning method according to claim 13, wherein a supply time of the cleaning fluid of two adjacent first annular closed-loop pipelines of the first annular closed-loop pipelines overlaps.

17. The cleaning method according to claim 13, wherein a supply time of the cleaning fluid of two adjacent first annular closed-circuit pipelines of the first annular closed-loop pipelines does not overlap.

18. The cleaning method according to claim 13, further comprising:
obtaining the cleaning fluid after cleaning the object to be cleaned;
performing a component analysis on the cleaning fluid that is obtained to obtain component analysis results; and
determining whether to end the cleaning process according to the component analysis results.

19. The cleaning method according to claim 18, further comprising:
performing feedback control of process parameters according to the component analysis results.

20. The cleaning method according to claim 13, further comprising:
automatically adjusting process parameters according to a type of a previous process before performing the cleaning process on the object to be cleaned.
